(19) United States
(12) Patent Application Publication
(10) Pub. No.: US 2015/0062847 A1
(43) Pub. Date: Mar. 5, 2015

(54) COMPONENT CONNECTION MEMBER, MOBILE COMMUNICATION DEVICE COMPRISING THE SAME AND MANUFACTURING METHOD THEREOF

(71) Applicant: Pantech Co., Ltd., Seoul (KR)

(72) Inventor: Sung June Park, Seoul (KR)

(21) Appl. No.: 14/477,274

(22) Filed: Sep. 4, 2014

(30) Foreign Application Priority Data
Sep. 5, 2013 (KR) 10-2013-0106797

(51) Int. Cl. H01Q 1/24; H05K 1/02; H05K 3/32; H05K 1/11

(52) U.S. Cl. CPC H01Q 1/24; H05K 1/11; H05K 1/0213; H05K 3/32
USPC 361/760; 29/832

(57) ABSTRACT

A component connection member, a mobile communication device comprising the same and a manufacturing method thereof include: a support structure, which is mounted on a substrate, formed to have at least one bent part; a first contact part connected to one end of the support structure and formed to come into contact with and be electrically connected to a first component disposed facing a first surface of the substrate; and a second contact part connected to the other end of the support structure and formed to come into contact with and be electrically connected to a second component disposed facing a second surface adjacent to the first surface of the substrate or a third surface opposite to the first surface of the substrate.

### CROSS-REFERENCE TO RELATED APPLICATION

This application claims priority from and the benefit under 35 U.S.C. §119(a) of Korean Patent Application No. 10-2013-0106797, filed on Sep. 5, 2013, which is incorporated by reference for all purposes as if fully set forth herein.

### BACKGROUND

1. Field

The present disclosure relates to a component connection member, a mobile communication device comprising the same and a manufacturing method thereof, and more particularly, to a component connection member that may connect components disposed in different directions using a simple method, a mobile communication device comprising the same, and a manufacturing method thereof.

2. Discussion of the Background

When applying a metal case to a mobile communication device, communication by an antenna can be obstructed due to properties of the metal case. To overcome this problem, attempts have been made to use a metal case as a part of an antenna by applying an electric current to the metal case and the antenna.

Specifically, FIG. 1 is a diagram illustrating a cross section of a mobile communication device 1 according to a related art.

Referring to FIG. 1, the mobile communication device 1 may have a case unit of the mobile communication device constructed by assembling a first case 21 and a second case 25. A first antenna 23 is formed to be attached to an inner surface of the first case 21, and the second case 25, also referred to as a second antenna, made of a metal, may be used as a second antenna.

To connect the first antenna 23 to the second antenna 25, many components need to be added, and the addition of components causes many problems such as high manufacturing costs, an increase in manufacturing cost per unit, an increase in procedural defect ratio, and the like.

More specifically, connection of the first antenna 23 to the second antenna 25 is established through a substrate 15. For example, the substrate 15 and the first antenna 23 may be connected by a first clip 11, and the second antenna 25 and the substrate 15 may be connected by a second clip 13. Also, the first clip 11 and the second clip 13 are connected through a conductive pattern 12 connecting the first clip 11 and the second clip 13 along the side surface of the substrate 15.

Particularly, in the connecting of the second antenna 25 disposed outside to the substrate 15 disposed inside, such connection is established by welding a nut 14 to the second antenna 25 or the second case, fitting a screw 19 into the nut 14, and forming a frame structure 17 to connect the screw 19 to the second clip 13.

During this process, because the conductive pattern 12, the frame structure 17, the screw 19, and the nut 14 are added, additional mounting and assembly operations for each component need to be added.

Particularly, the addition of the nut 14 and the screw 19 creates many problems. The addition of the welding process of the nut 14 to the second case 25 results in a significant reduction in production yield. Also, when a defect occurs in the nut 14, there is a drawback that the entire case should be discarded. A faulty tapping process of the nut 14 could lead to a screw fastening defect, and a position deviation of the nut 14 may result in the battery case on a product being loose.

Also, to tune this antenna pattern, a plurality of screws needs to be mounted, but as the number of screws increases, the defect ratio increases, and assembly process time, material costs, and manufacturing costs increase.

Furthermore, to form the conductive pattern 12 or after forming the frame structure 17, a plating process needs to be additionally performed. However, the addition of the plating process increases component manufacturing cost per unit. Also, because the clips for overall contact may be damaged during substrate delivery, there is a disadvantage of having to add a separate case to protect the clips.

### SUMMARY

Exemplary embodiments of the present invention provide a component connection member, a mobile communication device comprising the same and a manufacturing method thereof.

Exemplary embodiments of the present invention provide a mobile terminal including a substrate; a support structure mounted on the substrate, the support structure having at least one bent part; a first contact part and a second contact part connected to each end of the support structure; a first component element in contact with and electrically connected to the first contact part; and a second component in contact with and electrically connected to the second contact part.

Exemplary embodiments of the present invention provide a method for providing a mobile terminal: the method including forming a housing for the mobile terminal, the housing comprising a first case and a second case; disposing a first component in the inner surface of the first case; providing a support structure with a first contact part and a second contact part connected to each end of the support structure; mounting the support structure on a substrate; and connecting the first contact part to the first component and the second contact part to the second case.

It is to be understood that both forgoing general descriptions and the following detailed description are exemplary and explanatory and are intended to provide further explanation of the invention as claimed. Other features and aspects will be apparent from the following detailed description, the drawings, and the claims.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a cross-sectional view illustrating a mobile communication device according to a related art.

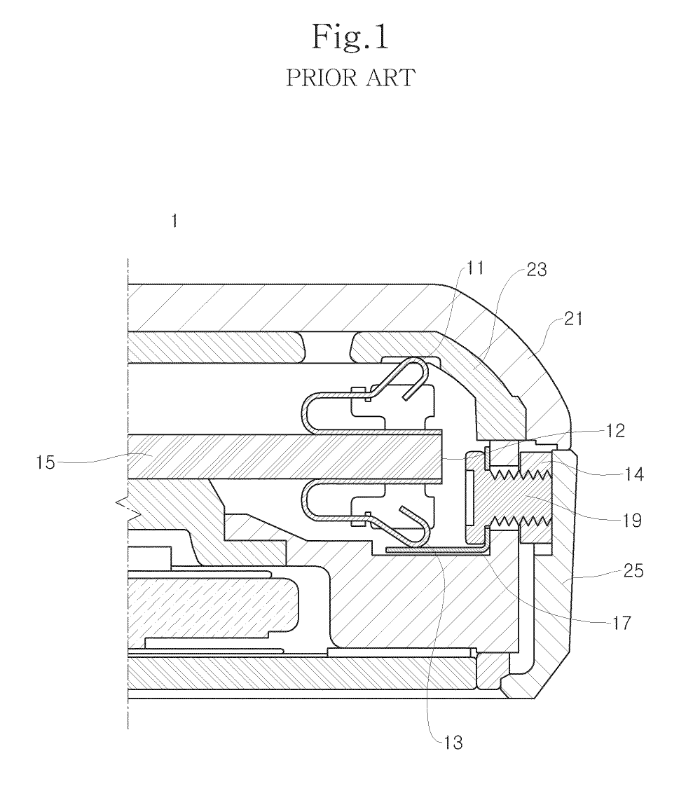

FIG. 2 is a perspective view illustrating a component connection member according to an exemplary embodiment of the present invention.

FIG. 3 is a cross-sectional view illustrating a mobile communication device having the component connection member of FIG. 2 mounted therein.

FIG. 4 is a perspective view illustrating a mobile communication device having a component connection member mounted therein according to an exemplary embodiment of the present invention.

FIG. 5 is an exploded view illustrating a component connection module and a substrate according to an exemplary embodiment of the present invention.

FIG. 6 is a cross-sectional view illustrating a mobile communication device having the component connection module according to the embodiment of FIG. 5 mounted therein.

FIG. 7 is a perspective view illustrating a component connection member and an assembled state of the connection member in a device according to an exemplary embodiment of the present invention.

FIG. 8 is a perspective view illustrating a component connection member and an assembled state of the connection member in a device according to an exemplary embodiment of the present invention.

FIG. 9 is a cross-sectional view illustrating a mobile communication device having the component connection member of FIG. 7 mounted therein.

### DETAILED DESCRIPTION OF THE ILLUSTRATED EMBODIMENTS

Exemplary embodiments now will be described more fully hereinafter with reference to the accompanying drawings, in which exemplary embodiments are shown. The present disclosure may, however, be embodied in many different forms and should not be construed as limited to the exemplary embodiments set forth therein. Rather, these exemplary embodiments are provided so that the present disclosure will be thorough and complete, and will fully convey the scope of the present disclosure to those skilled in the art. In the description, details of well-known features and techniques may be omitted to avoid unnecessarily obscuring the presented embodiments.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. Furthermore, the use of the terms a, an, etc. does not denote a limitation of quantity, but rather denotes the presence of at least one of the referenced item. The use of the terms “first”, “second”, and the like does not imply any particular order, but they are included to identify individual elements. Moreover, the use of the terms first, second, etc. does not denote any order or importance, but rather the terms first, second, etc. are used to distinguish one element from another. It will be further understood that the terms “comprises” and/or “comprising”, or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

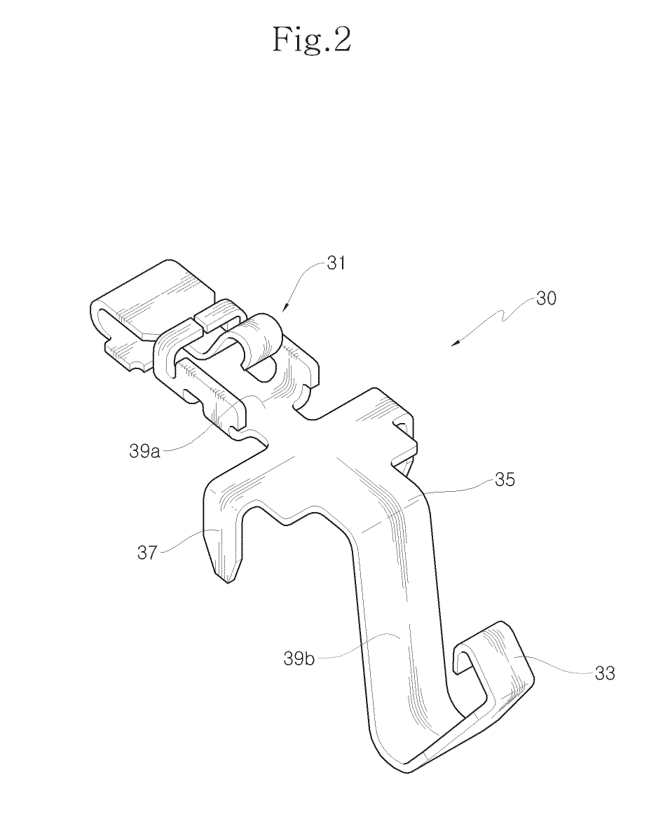

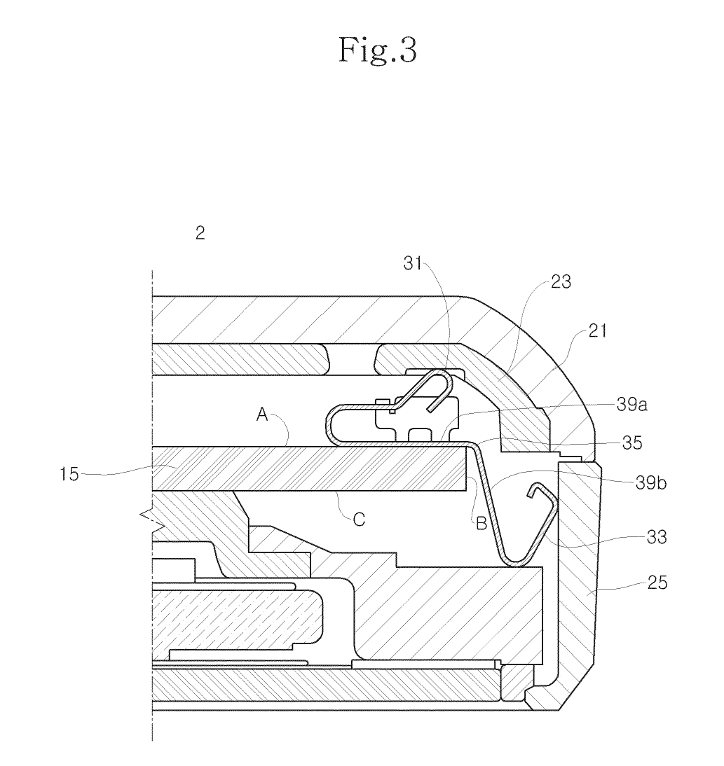

FIG. 2 is a perspective view illustrating a component connection member 30 according to an exemplary embodiment of the present invention, and FIG. 3 is a cross-sectional view illustrating the component connection member 30 according to the embodiment of FIG. 2 in a mounted state in a mobile communication device 2.

Referring to FIGS. 2 and 3, the component connection member 30 according to an exemplary embodiment includes a support structure 35, and a first contact part 31 and a second contact part 33 connected to each end of the support structure 35, respectively. The support structure 35 may be formed to have at least one bent part. Accordingly, the support structure 35 may connect components disposed in various directions.

As illustrated in FIG. 3, the component connection member 30 according to an exemplary embodiment is mounted on the substrate 15. The component connection member includes the support structure 35 formed to have at least one bent part, the first contact part 31 connected to one end of the support structure 35 and formed to come into contact with and be electrically connected to a first component disposed facing a first surface A of the substrate, and the second contact part 33 connected to the other end of the support structure 35 and formed to come into contact with and be electrically connected to a second component disposed facing a second surface B adjacent to the first surface A of the substrate or a third surface C opposite to the first surface A of the substrate.

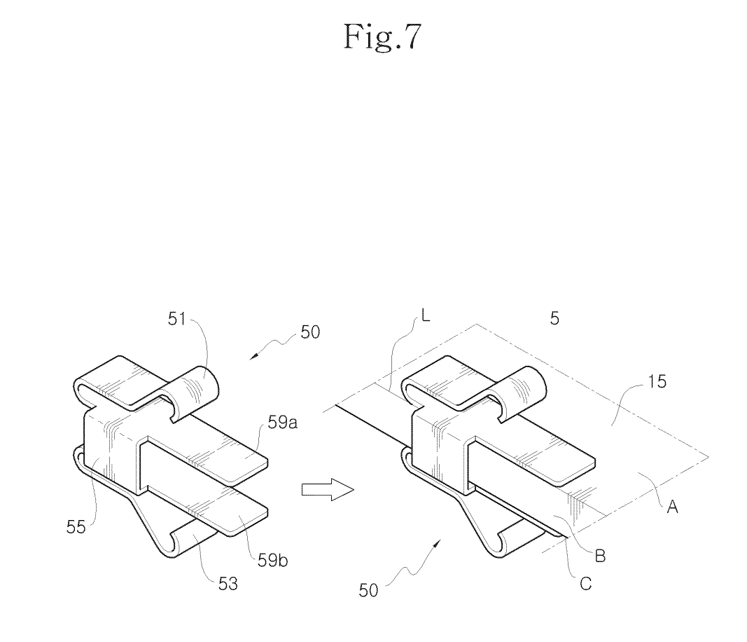

In particular, the support structure 35 according to an exemplary embodiment may be formed to connect the first component disposed facing the first surface A or any one surface formed on the substrate to the second component disposed facing the second surface B or the third surface C that is different in direction from the first surface A. Although the embodiments of FIGS. 2 through 6 show the connection of components disposed in the first surface A direction and the second surface B direction adjacent thereto, and the embodiments of FIGS. 7 through 9 show the connection of components disposed in the first surface A direction and the third surface C direction opposite thereto, the present disclosure is not necessarily limited thereto, and the support structure may be formed to have a bent part which is bent at various angles to connect components disposed in various directions.

Also, the support structure 35 may be disposed at the end portion of the substrate 15, and may be disposed to be hung on the end as illustrated in FIGS. 2 through 6 or may be placed on the end as illustrated in FIGS. 7 through 9.

Accordingly, the support structure 35 may be formed to connect components disposed in various directions at the end portion of the substrate 15.

According to an exemplary embodiment, the first contact part 31 may be formed to come into contact with the first component disposed in the first surface A direction of the substrate 15, and the second contact part 33 may be formed to come into contact with the second component disposed in the second surface B or the third surface C direction of the substrate 15.

The first contact part 31 and the second contact part 33 may be made in a shape of a plate spring such that the first contact part 31 and the second contact part 33 are elastic against the first surface A and the second surface B or the third surface C, respectively. Accordingly, the contact may be more reliable.

As illustrated in FIG. 2, according to an exemplary embodiment, the support structure 35 may also include at least one fixing part 37 drawn from the support structure 35 and formed to be inserted into the substrate 15. The fixing part 37 may not only serve to fix the support structure 35 to the substrate but also serve to electrically connect the support structure 35 to a component or circuit of the substrate 15. Although the embodiment of FIG. 2 shows two fixing parts 37 formed to be drawn out from the support structure 35, the present disclosure is not necessarily limited thereto, and one or more fixing part(s) drawn out in different directions may be provided.

Although the present disclosure shows and describes that the component connection member connects, for example, a first antenna and a second antenna disposed in different directions in the mobile communication device, the present disclosure is not necessarily limited thereto, and various components disposed in different directions may be the first component and the second component.

Referring to FIG. 3, the component connection member 30 according to an exemplary embodiment of the present invention may be applied in the mobile communication device 2.

A case of the mobile communication device 2 may be provided by assembling at least one case. In the exemplary embodiment of FIG. 3, the part disposed facing down in the drawing represents a display part which displays an image and the part disposed facing up represents a rear part where a battery or the like is disposed.

According to an exemplary embodiment, the mobile communication device 2 may be formed such that the first case 21 disposed on the rear surface is connected to the second case 25 disposed on the side surface directly or indirectly by the medium of another case.

The first case 21 may be formed to embed the first antenna 23 therein. The first case 21 may be formed, for example, by injection molding in a state in which the first antenna 23 is included in the inner surface of the first case 21. But the method for forming the first case 21 with the first antenna embedded is not necessarily limited thereto, and the first case 21 may be formed to attach the first antenna 23 thereto in an inner surface of the device by various methods.

The second case 25 may be a side case formed to surround the mobile communication device 2, and may be integrally formed to improve the strength of a product and the like. According to an exemplary embodiment, the second case 25 may be a side metal case formed to surround the side surface of the mobile communication device 2.

When the second case 25 is formed in a metal case, the second case 25 may be used as a second antenna which may be connected to the first antenna 23 to improve the performance of the first antenna 23. Accordingly, the second case 25 used as a second antenna, may be also referred to as a ‘second antenna’ 25.

The component connection member 30 may be used to connect the first antenna 23 formed in the first case 21 to the second antenna 25.

One end of the support structure 35 may have a first support surface 39a which may be disposed on the first surface A of the substrate 15. The first support surface 39a may be adhered on the surface of the substrate 15. For example, the first support surface 39a may be welded, soldered, attached, fixed, or the like on the surface of the substrate 15. Further, an adhesive, an adhesive tape, or the like may be disposed between the first support surface 39a and the one end of the support structure 35. The other end of the support structure 35 may have a second support surface 39b which may be disposed in the second surface B direction. The first support surface 39a and the second support surface 39b may be connected by a bent part of the support structure 35.

Although the embodiment of FIG. 3 shows that only the first support surface 39a is adhered on the surface A of the substrate 15 and the second support surface 39b is not in a close contact with the second surface B, the present disclosure is not necessarily limited thereto, and both the first and second support surfaces 39a and 39b may be welded, soldered, attached, fixed, or the like, on different surfaces of the substrate 15. Further, an adhesive, an adhesive tape, or the like may be disposed between both the first and second support surfaces 39a and 39b and different surfaces of the substrate 15.

The first support surface 39a may be formed to be connected to the first contact part 31 to come into contact with the first antenna 23. The second support surface 39b may be formed to be connected to the second contact part 33 to come into contact with the second antenna 25.

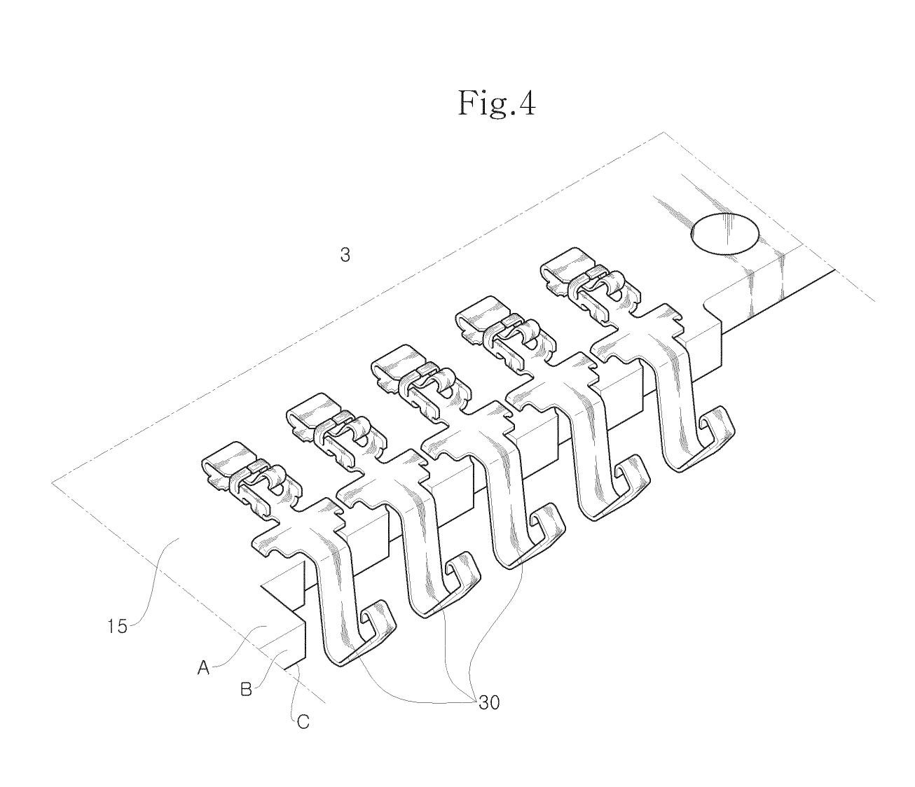

FIG. 4 is an internal exploded perspective view illustrating an inside of a mobile communication device 3 in which the component connection member 30 according to an exemplary embodiment is mounted on the substrate 15.

According to an exemplary embodiment, at least one component connection member 30 may be disposed at the end portion of the substrate 15. The antenna characteristics may change based on a location of the substrate 15, a contact location with the first antenna 23, and a contact location with the second antenna 25.

Accordingly, when assembling a mobile communication device, an antenna tuning operation is needed to adjust the contact locations.

In the embodiment of FIG. 4, considering the antenna characteristics, at least one component connection member 30 may be disposed at the end portion of the substrate 15 where the first antenna 23 and the second antenna 25 are connected, to allow a connection with the first antenna and a connection with the second antenna to be established at a desired location.

An antenna tuning operation may be performed by controlling a number of component connection members or a number of branches to be described later, or by adjusting a location of a component connection member or a branch to be connected, during antenna tuning.

For antenna tuning, to select a first contact part and a second contact part of a desired component connection member 30 and to connect them to the first antenna 23 or the second antenna 25, first contact part(s) and second contact part(s) apart from those selected may be shorted or open.

More specifically, in the fixed component connection member, to allow only desired first and second contact parts to come into contact with the first antenna 23 or the second antenna 25 and to preclude the remaining first and second contact parts from coming into contact with the first antenna 23 or the second antenna 25, antenna tuning may be performed by adjusting the contact location by, for example, bending, cutting, or interposing an insulation material.

During antenna tuning at the product development stage, as a number of essential factors affecting the tuning increases, the number of tuning tests increases. However, according to the exemplary embodiment, where only one component connection member is used to connect antennas, the number of essential factors affecting the antenna tuning reduces. Thus, tuning may be performed quickly in a simple and easy manner, and antenna performance may be ensured.

According to an exemplary embodiment, a tuning or testing operation may be performed within a very short time and performance may be ensured at an earlier time, compared to a conventional method such as screw clamping or the like.

According to an exemplary embodiment, the component connection member 30 may be mounted on the substrate by a surface mount technology (SMT), or may be manufactured as a component connection module which is formed to be assembled on the substrate.

More specifically, during the substrate processing, the substrate may be prepared in a state in which the component connection member 30 is pre-mounted on the substrate. Also, an electrical connection of the first antenna 23 and the second antenna 25 may be established by assembling the substrate 15 between the first case 21 and the second case 25. Accordingly, the first antenna 23 and the second antenna 25 may be connected by a simple method without going through additional conventional processes to add components such as a screw, a nut, and a plating process of a conductive pattern.

Finally, according to an exemplary embodiment, manufacturing the mobile communication device may be implemented in a simple and easy manner, and due to the component connection member being prepared in a pre-mounted state, a defect ratio that occurs during an assembly process may be reduced. Also, because various components and a plating process or an assembly process does not need to be added, the product cost and the assembly cost may be reduced and the assembly time may also be shortened.

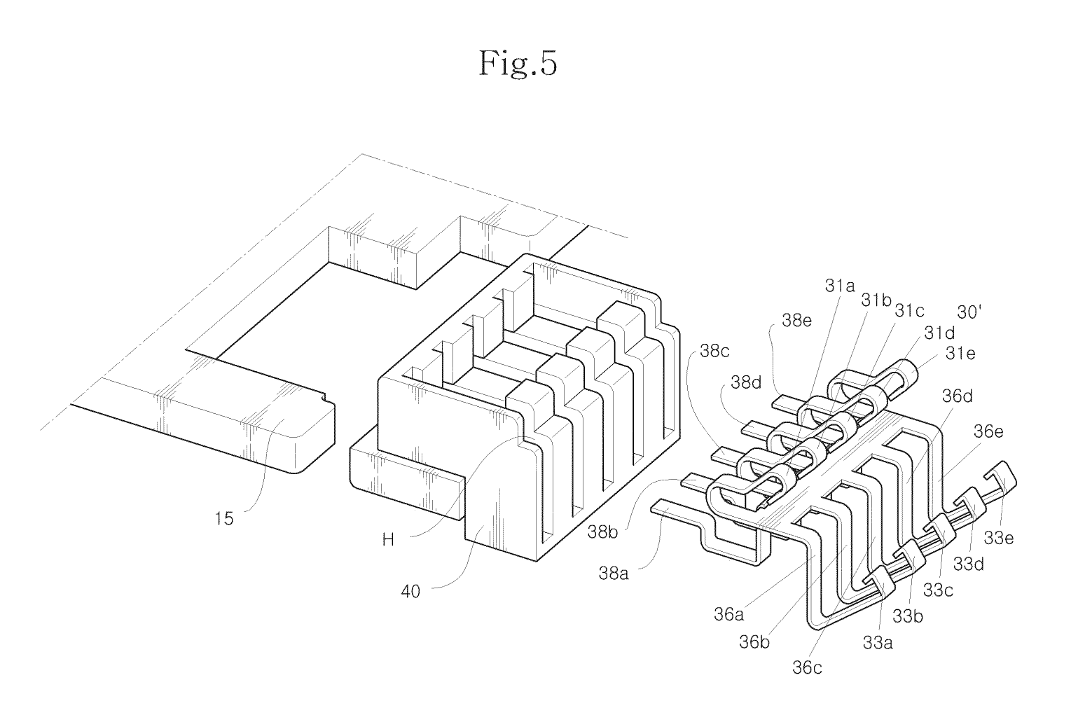

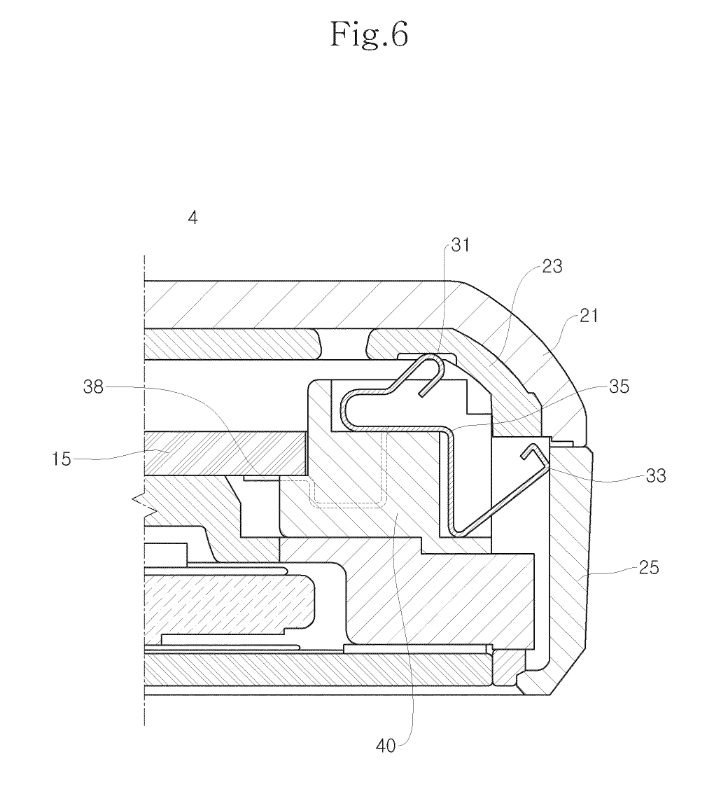

FIG. 5 is an exploded view illustrating a component connection module according to an exemplary embodiment of the present invention. FIG. 6 is a cross-sectional view illustrating a cross section of a device 4 having the component connection module according to the embodiment of FIG. 5 mounted therein. According to the exemplary embodiments of FIGS. 5 and 6, the component connection member may be formed to be assembled in a modular state and assembled on a substrate, but not mounted on a substrate.

As illustrated in FIGS. 5 and 6, according to an exemplary embodiment, the component connection module 30′ includes a housing 40 in which the support structure 35 is mounted on, and a drawn fixing part 38 (see FIG. 6) connected to the support structure 35 and drawn outside the housing 40 to form a connection terminal to the substrate.

Accordingly, the component connection member 30′ may be provided in a state of a component connection module after being coupled with the housing 40. The component connection module in a mounted state on the substrate 15 may be assembled between the first case 21 and the second case 25, which may connect the first antenna 23 and the second antenna 25.

Thus, as illustrated in FIG. 5, the component connection member 30′ may be mounted on the substrate 15 only by a process of assembling the component connection module on the substrate. When a product is provided in a modularized state, the mobility of the product may increase, and detachment and replacement of the product may be facilitated.

Meanwhile, the support structure 35 is formed by connecting at least one of branches 36a, 36b, 36c, 36d, and 36e having at least one bent part. Each of the branches 36a, 36b, 36c, 36d, and 36e may be formed to be connected to first contact parts 31a, 31b, 31c, 31d, and 31e at one end and second contact parts 33a, 33b, 33c, 33d, and 33e at the other end.

Because the component connection member is composed of a support structure 35 including the at least one branch 36a, 36b, 36c, 36d, and 36e connected, a cumbersome task of attaching the component connection member to the substrate one by one may be avoided. Also, the component connection member including the support structure 35 composed of a plurality of branches may be also mounted on the substrate by a surface mount technology, and as shown in FIG. 5, may be provided in a type of a module after being mounted on the housing 40.

Specifically, the component connection module includes the housing 40 for mounting the support structure 35 formed by connecting at least one of branches 36a, 36b, 36c, 36d, and 36e, in which the branches 36a, 36b, 36c, 36d, and 36e include the first contact parts 31a, 31b, 31c, 31d, and 31e and the second contact parts 33a, 33b, 33c, 33d, and 33e, respectively connected to each end, and at least one drawn fixing part 38a, 38b, 38c, 38d, and 38e each connected to the branches 36a, 36b, 36c, 36d, and 36e and drawn outside the housing to form a connection terminal to the substrate.

As illustrated in FIG. 5, according to an exemplary embodiment, the substrate 15 or the housing 40 may have a mounting hole H to include the support structure, the drawn fixing part, a portion of the first contact part, and a portion of the second contact part therein, and the housing 40 may be molded by an insert injection molding process or the like, in a state in which the housing 40 includes the component connection member inside.

According to an exemplary embodiment, the substrate 15 or the housing 40 may include the mounting hole H for mounting the support structure 35 to protect a portion of the first contact part 31 and a portion of the second contact part 33 within the housing 40.

Although the embodiment of FIG. 5 shows that the mounting hole H is disposed in the housing for modularization, the mounting hole H is not necessarily limited thereto and may be disposed at the end part of the substrate 15.

When the component connection member is entirely exposed, there was a concern about damage of the connection member during component transfer or assembly with other component, however because the mounting hole H is formed to protect the support structure, a portion of the first contact part and a portion of the second contact part inside the hole H, damage of the component connection member that may occur during product delivery may be decreased. Also, a need for a separate case for protecting the component connection member is eliminated.

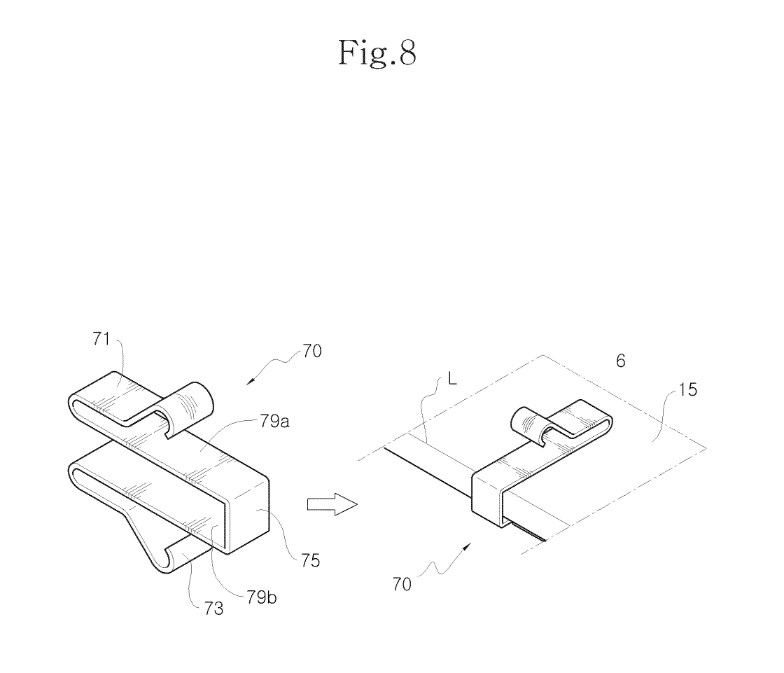

FIG. 7 is an internal exploded perspective view illustrating a component connection member according to an exemplary embodiment and an inside of a device 5 in which the connection member is assembled, and FIG. 8 is an internal exploded perspective view illustrating a component connection member according to an exemplary embodiment and an inside of a device 6 in which the connection member is assembled.

The component connection members 50 and 70 according to the embodiments may include first support surfaces 59a and 79a which are disposed on the first surface A of the substrate 15, second support surfaces 59b and 79b which are disposed on the third surface C opposite to the first surface A, and support structures 55 and 75 connecting the first support surfaces 59a and 79a and the second support surfaces 59b and 79b. Also, the component connection members 50 and 70 may be formed to include first contact parts 51 and 71 connected to one end of the first support surfaces 59a and 79a and second contact parts 53 and 73 connected to one end of the second support surfaces 59b and 79b.

The component connection members 50 and 70 according to the embodiments of FIGS. 7 and 8 are formed such that the first support surfaces 59a and 79a, the support structures 55 and 75, and the second support surfaces 59b and 79b surround an end portion of the substrate, the end portion of the substrate 15 fitting into the component connection members 50 and 70. Accordingly, the component connection members 50 and 70 may be assembled by a more simple and easy method.

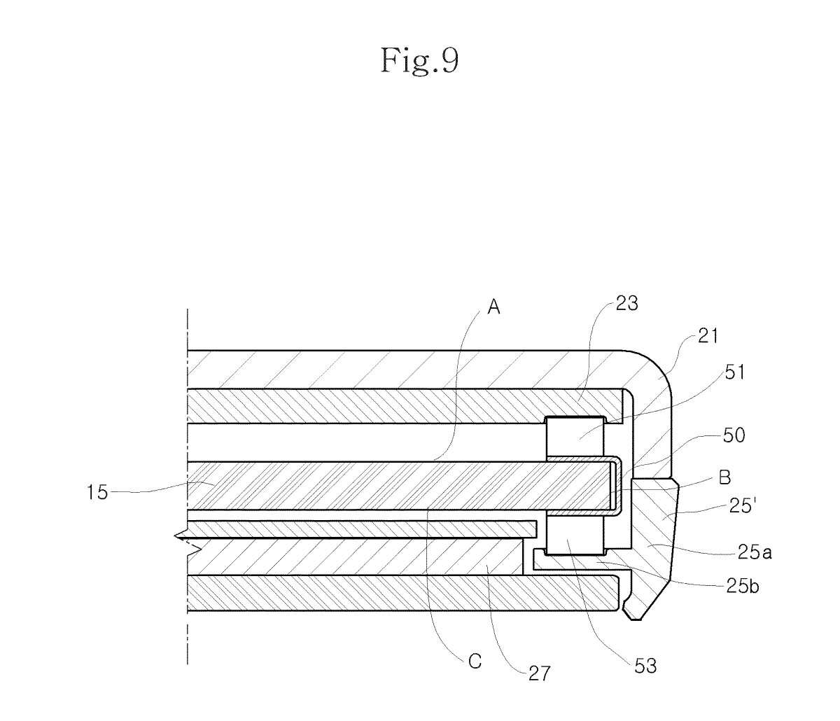

For example, referring to FIG. 7, the first contact part 51 and the second contact part 53 may be connected to the first support surface 59a and the second support surface 59b, and formed to extend along an end line L of the substrate 15. Thus, when the component connection member 50 is placed on the end portion of the substrate, the first contact part 51 and the second contact part 53 may be disposed to extend along the end line L of the substrate. Accordingly, the component connection member 50 may be formed to be mounted on a narrow space at an edge of the substrate 15 (see FIG. 9).

That is, according to the exemplary embodiment, in the design of the substrate 15, the component connection member 50 that may connect the components by making use of the narrow space at the edge may be provided. Accordingly, the connection member 50 with high flexibility that may be applicable to various components may be provided.

Referring to FIG. 8, the first contact part 71 or the second contact part 73 may be connected to the first support surface 79a and the second support surface 79b, and formed to extend in a direction crossing the end line L of the substrate 15. Accordingly, the component connection member 70 may connect components formed at various locations near the substrate 15 as well as components formed near the end portion of the substrate 15.

Although the embodiments of FIGS. 7 and 8 show that both the first contact part and the second contact part are disposed in the same direction with respect to the substrate, the first contact part and the second contact part are not necessarily limited thereto, and any one of the first contact part and the second contact part may be disposed to extend along the end line L of the substrate 15 and the remaining contact part may extend in a direction crossing the end line L of the substrate 15.

FIG. 9 is a cross-sectional view illustrating a state in which the component connection member 50 of FIG. 7 is assembled in a device.

Referring to FIG. 9, in connecting the first antenna 23 disposed within the first case 21 to the second case 25′ or a metal side case, the component connection member 50 according to the embodiment of FIG. 7 may be mounted on the substrate 15.

Specifically, as illustrated in FIG. 9, the first case 21 may be a case which forms a rear surface of the device where the first antenna 23 is embedded or attached, while a display unit 27 is disposed facing down.

The second case 25′ may be, for example, a metal case which forms a side surface of the device. The first case 21 may be disposed in the first surface A direction of the substrate 15, and the second case 25′ may further include a first frame 25a disposed in the second surface B direction adjacent to the first surface A of the substrate, and a second frame 25b extending from the first frame 25a toward the third surface C opposite to the first surface A.

Accordingly, the first case 21, and the first frame 25a and the second frame 25b of the second case 25′ in a sequential order may form a ‘C-type’ or ‘symmetrical C-type’ structure. Although the exemplary embodiment as illustrated in FIG. 9 shows an embodiment of forming a ‘symmetrical C-type’ structure, the present disclosure is not necessarily limited thereto, and placement may be made to have a ‘C-type’ structure. Thus, the first contact part 51 of the component connection member 50 may be connected to the first case 21 disposed in the first surface A direction, and the second contact part 53 may be connected to the second frame 25b of the second case 25′ disposed in the third surface C direction.

Particularly, with regard to the component connection member 50 of the exemplary embodiment in FIG. 9, due to it being capable of connecting the components even when mounted on a narrow space at the edge of the substrate, even if the second frame 25b has a short length extending in the third surface C direction, the second frame 25b, also referred to as the second antenna 25′, may be connected to the first antenna 23. Therefore, according to the exemplary embodiment, minimization of the device may be achieved by reducing a width between the component connection member 50 and an edge frame, the second frame 25b, of the device.

If the second frame 25b is disposed in the third surface C direction, when utilized as a structure in which a display panel or a cover glass covering the display panel are disposed, such application may minimize the thickness of the device. In addition, because the first antenna 23 and the second antenna 25′ are connected by the component connection member 50, a stable connection of the antennas may be ensured and signal loss may be minimized, and moreover, slimming and minimization of the device may be achieved by optimizing the component placement inside the device.

According to an exemplary embodiment, the component connection member which may connect components disposed in a vertical or horizontal direction may be provided. Thus, compared to a conventional structure where many complicated components need to be added to connect components, in the exemplary embodiment components may be connected by just one member, the component connection member.

Because the component connection member of the present disclosure may be provided in a unitary connected state, the strength of a product may be improved, the damage to components may be decreased, and component handling may be facilitated when compared to a structure where a plurality of components are connected. By simplifying a signal connection structure, signal loss may be minimized at each transmission step, and as a result, signal transmission efficiency and performance of the antenna may be improved.

Also, a method of manufacturing the mobile communication device according to an exemplary embodiment includes preparing the first case 21 in which the first antenna 23 is disposed in an inner surface of the device, the second case comprising the second antenna 25, made of a metal and disposed in an outer surface of the device, and the substrate 15 disposed within the device, and mounting the at least one component connection member 30 on the substrate 15, the component connection member 30 including the support structure 35 formed to have at least one bent part, the first contact part 31 connected to one end of the support structure 35 and formed to come into contact with and be electrically connected to the first antenna disposed facing the first surface A of the substrate, and the second contact part 33 connected to the other end of the support structure 35 and formed to come into contact with and be electrically connected to the second antenna 25 disposed facing the second surface B adjacent to the first surface A of the substrate or the third surface C opposite to the first surface A.

The mounting of the component connection member may include mounting the component connection member 30 on the substrate by a surface mount technology, or assembling as a component connection module.

To tune the first antenna 23 and the second antenna 25, at least one component connection member selected among the at least one or more component connection members mounted on the substrate 15 may be shorted, and a remaining component connection member among the at least one or more component connection member may be open.

According to the method of manufacturing the mobile communication device according to the exemplary embodiment, because the component connection member may be mounted on the substrate by a surface mount technology or a modular technology, a mounting process may be simplified to a simple method and a defect ratio may be reduced. Thus, costs incurred by faulty products may be reduced.

The component connection member of the present disclosure may be disposed at a corresponding location to the antenna. For antenna tuning, at least one component connection member may be disposed, or a component connection member having a plurality of branches may be disposed. Also, tuning may be performed in a simple manner by only a process that causes each component connection member or each branch to be shorted or open.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A mobile terminal, comprising:
a substrate;
a support structure mounted on the substrate, the support structure having at least one bent part;
a first contact part and a second contact part connected to each end of the support structure;
a first component element in contact with and electrically connected to the first contact part; and
a second component in contact with and electrically connected to the second contact part.

2. The mobile terminal in claim 1, wherein the support structure is mounted on an end portion of the substrate.

3. The mobile terminal in claim 1, wherein the first component is disposed facing a first surface of the substrate, and the second component is disposed facing a second surface of the substrate.

4. The mobile terminal in claim 2, wherein the support structure further comprises:
a first support surface between the bent part and the first contact part, the first support surface being disposed on the first surface of the substrate, and
a second support surface between the bent part and the second contact part, the second support surface being disposed on the second surface of the substrate.

5. The mobile terminal in claim 3, wherein the first surface of the substrate and the second surface of the substrate are located adjacent to each other.

6. The mobile terminal in claim 3, wherein the first surface of the substrate and the second surface of the substrate are located opposite to each other.

7. The mobile terminal in claim 1, wherein the support structure further comprises one or more fixing parts, the fixing parts inserted to the substrate to electrically connect the support structure to the substrate.

8. The mobile terminal in claim 1, wherein
the first component is disposed on the inner surface of a first case of the mobile terminal, the first component being the first antenna, and
the second component is a second metal case of the mobile terminal, the second component being the second antenna.

9. The mobile terminal of claim 3, wherein the first support surface and the second support surface are adhered to the first surface of the substrate and the second surface of the substrate, respectively.

10. The mobile terminal of claim 1, further comprising branches of the support structure connected to the first contact part and the second contact part.

11. The mobile terminal of claim 10, wherein the branches or the first contact part and second contact part not connected to the first antenna and the second antenna are shorted.

12. The mobile terminal of claim 3, wherein the support structure, the first support surface, the second support surface, the first contact part and the second contact part are coupled with a housing element comprising a mounting hole, the housing element mounted on the substrate.

13. The mobile terminal of claim 6, wherein the first support surface and the second support surface extend in a direction parallel to an end line of the first surface of the substrate.

14. The mobile terminal of claim 6, wherein the first support surface and the second support surface extend in a direction crossing the end line of the first surface of the substrate.

15. A method for providing a mobile terminal, the method comprising:
forming a housing for the mobile terminal, the housing comprising a first case and a second case;
disposing a first component in the inner surface of the first case;
providing a support structure with a first contact part and a second contact part connected to each end of the support structure;
mounting the support structure on a substrate; and
connecting the first contact part to the first component and the second contact part to the second case.

16. The method of claim 15, further comprising disposing the first component to face a first surface of the substrate and the second case to face a second surface of the substrate.

17. The method of claim 16, further comprising disposing a first support surface on a the first surface of the substrate and a second support surface structure on the second surface of the substrate,
wherein the first support surface and the second support surface are connected to a bent portion of the support structure and the first contact part and the second contact part, respectively.

18. The method of claim 15, further comprising shorting branches of the first contact parts and the second contact parts not connected to the first component and the second component.

19. The method of claim 15, wherein the support structure, the first contact part, and the second contact part are coupled to a mounting hole of a housing unit mounted on the substrate.

20. The method of claim 15, further comprising inserting a fixing structure connected to the support structure to the substrate.

21. The method of claim 17, wherein the first support surface and the second support surface are disposed in a direction parallel to an end line of the first surface of the substrate.

22. The method of claim 17, wherein the first support surface and the second support surface are disposed in a direction crossing the end line of the first surface of the substrate.
